(19) United States
(12) Patent Application Publication
(10) Pub. No.: US 2008/0079116 A1
(43) Pub. Date: Apr. 3, 2008

(54) MOS varactor

(76) Inventors: Luo Yuan, Sunnyvale, CA (US); Derchang Kau, Cupertino, CA (US); Wei-Kai Shih, Beaverton, OR (US); Shafqat Ahmed, San Jose, CA (US); Brian K. Armstrong, Colorado Springs, CO (US)

Correspondence Address: TROP PRUNER & HU, PC, 1616 S. VOSS ROAD, SUITE 750, HOUSTON, TX, 77057-2631, US

(21) Appl. No.: 11/542,540

(22) Filed: Oct. 3, 2006

(51) Int. Cl. H01L 29/00

(52) U.S. Cl. 257/531

(57) ABSTRACT

An MOS varactor may be formed without tip implants or HALO implants. As a result, parasitic resistance may be reduced, jitter may be improved, and the quality factor may be increased, as well as the tunable range of the varactor.

### BACKGROUND

This relates generally to integrated circuits and, in particular, to a variable capacitor in a complementary metal oxide semiconductor (CMOS) process technology.

To achieve high data rate transmissions, components that have high levels of integration, low power consumption, and low jitter are desirable. Jitter is the short-term variation of a digital signal's significant instants from their ideal positions and times. Transceivers used in such communications may be implemented in complementary metal oxide semiconductor technology. To obtain high transmission rates, oscillators with low jitter gain are usually inductor-capacitor tank voltage controlled oscillators called LC tank VCOs.

What limits the noise in an LC tank is its small quality factor (Q), which is a measure of the LC tank's frequency response. A degraded Q causes the center frequency of the LC tank to shift and its output jitter to increase. The quality factor of an LC tank is a function of the inverse of the equivalent capacitance. Generally, CMOS voltage controlled capacitors have not had ideal quality factors.

### BRIEF DESCRIPTION OF THE DRAWINGS

FIG. 1 is an enlarged, cross-sectional view of one embodiment of the present invention;

FIG. 2 is an enlarged, cross-sectional view of the embodiment shown in FIG. 1 at an early stage of manufacture;

FIG. 3 is an enlarged, cross-sectional view of the embodiment shown in FIG. 2 at a subsequent stage of manufacture in accordance with one embodiment of the present invention;

FIG. 4 is a schematic diagram of an equivalent circuit of a portion of a CMOS varactor in accordance with one embodiment of the present invention;

FIG. 5 is a high level block diagram of a CMOS transceiver according to embodiments of the present invention; and

FIG. 6 is a high level block diagram of a communication system according to one embodiment of the present invention.

### DETAILED DESCRIPTION

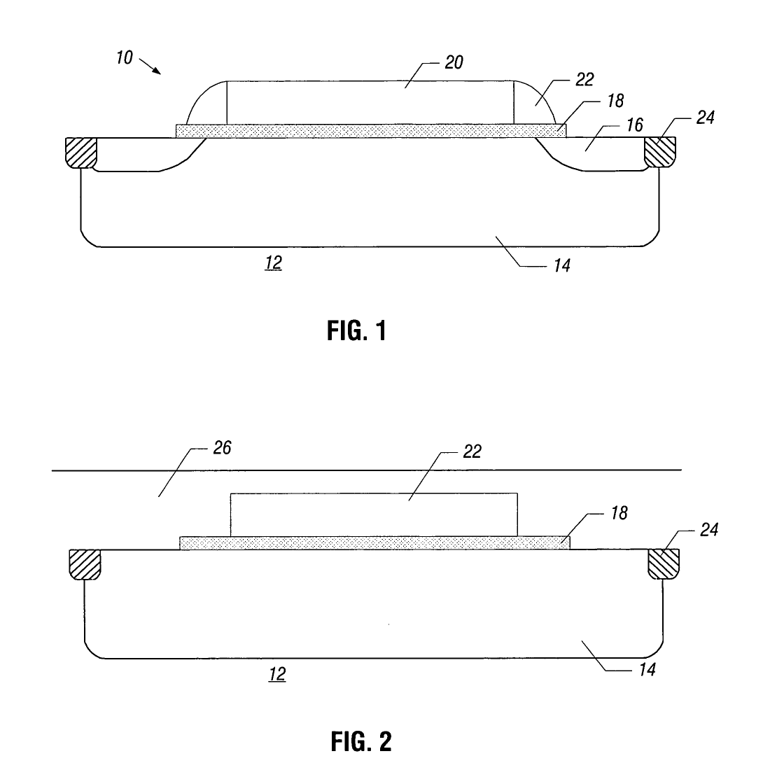

Referring to FIG. 1, a complementary metal oxide semiconductor (CMOS) varactor 10 may be formed in a semiconductor substrate 12. In one embodiment, the substrate may be lightly doped P-type silicon. An n-well 14 may be formed within the substrate 12. In one embodiment, the n-well 14 may be formed of lightly doped N-type silicon. Also formed within the n-well 14 are heavily doped N-type source/drain regions 16. A trench oxide 24 defines the position of the n-well 14 and the limits of the source and drain regions 16.

Formed over the n-well 14 is a gate oxide 18 and a gate electrode 20. In one embodiment, the gate electrode 20 is heavily doped N-type polysilicon. Sidewall spacers 22 on the sides of the gate electrode 20 define the positioning for source and drain regions 16.

Unlike conventional MOS varactors, the varactor 10 has neither a P-type tip or lightly doped source/drain, nor a HALO or pocket implant. Including these items, however, has been found by the present inventors to contribute to resistance which adversely affects the quality factor of the resulting varactor.

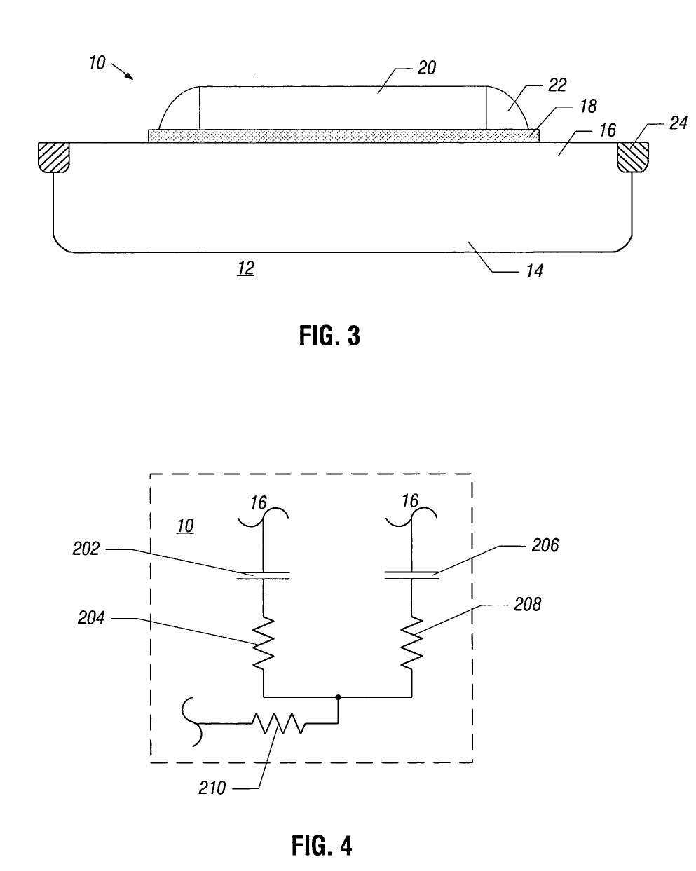

The process for forming the varactor 10 without the P-type HALO or tip implant is shown in FIGS. 2 and 3. After defining the structure shown in FIG. 2 with the trench oxide 24 in the substrate 12 and the n-well 14, the gate oxide 18 and a polysilicon gate electrode 20 may be formed. This structure may then be covered with a suitable mask 26 to prevent the lightly doped drain and HALO implants from entering the varactor 10. Thus, the tip and HALO implants may be used to form conventional transistors in other parts of the processed semiconductor wafer, but the regions where the varactors are to be formed may be masked to prevent the tip and HALO implants from entering the n-well 14.

Thereafter, the mask 26 is removed and the sidewall spacers 22 are formed as shown in FIG. 3. Then, the source/drain implants are undertaken to form the source and drain regions 16 and to highly dope the gate electrode 20, as shown in FIG. 1.

In some embodiments of the present invention, a single dopant polarity is utilized for the gate electrode 20, the channel, and the source/drain regions 16. The gate electrode 20 may be polysilicon, which is relatively heavily doped compared to the doping within the channel, which, relatively speaking, is lightly doped. In the same context, the source/drain regions 16 are relatively heavily doped. Thus, an abrupt doping profile may be seen from channel to source/drain region 16.

A lightly doped drain implant in a well tends to be the opposite dopant polarity from the well polarity. The lightly doped drain implant in an N-well creates highly resistive P-type regions near the varactor source/drain regions 16, degrading the varactor quality factor under accumulation biasing conditions. The regions with opposite dopant polarity underneath the gate electrode 20 also reduce the available capacitance tuning range. In some embodiments of the present invention, by eliminating P-type lightly doped drain implants in the MOS varactors, capacitance tuning range and quality factor under accumulation biases may be substantially improved. Reducing the channel doping concentration makes more abrupt capacitance transitions from depletion to accumulation regimes.

With conventional MOS varactors, high capacitance may be achieved when the gate voltage is more positive than the source/drain voltage under accumulation biases. Low capacitance may be achieved when gate voltages are more negative than the source/drain voltage in what may be known as depletion biases. A lightly doped drain implant into an N-well introduces P-type regions near the source/drain regions, increasing the channel resistance and reducing the varactor quality factor in the accumulation biasing conditions. On the other hand, when the N channel region is under depletion biases, the P-type regions will be in accumulation and, therefore, the minimum achievable capacitance value is raised. Furthermore, in deep depletion, P-type regions may be inverted by negative gate biases, leading to an increase in varactor capacitance.

In some embodiments, the single dopant polarity across the channel and source/drain region creates a relatively lower resistance current path, improving varactor quality factor in accumulation. A lightly doped region under the gate electrode could be relatively easily depleted. Therefore, some embodiments can achieve smaller minimum depletion capacitance with a more abrupt transition between depletion and accumulation regimes.

Similar advantages may be achieved with P-type accumulation MOS varactors with dopant polarities reversed for well, gate, and source/drain. By reversing the dopant polarities, high capacitance may be achieved when gate voltages are more negative than source/drain voltage (accumulation biases) and low capacitance may be achieved when gate voltage is more positive than source/drain voltage (depletion biases).

An equivalent circuit for the varactor 10 is shown in FIG. 4. The equivalent circuit 10 shows the capacitance 202 and a resistance 204 coupled in series with one of the source/drain regions 16. Similarly, a resistance 208 and a capacitance 206 are connected to the other of the source/drain regions 16. By the elimination of the P-type tip and HALO implants, the resistances 204 and 208 may be substantially reduced. The resistance 210 is a result of the metallization lines coupled to the varactor 10.

Because the series resistances 204 and 208 are parasitic resistances, they tend to reduce the quality factor of the differential capacitance created by the source/drain regions 16. As the quality factor of the differential capacitance degrades, the jitter in any LC tank using the varactor 10 increases. The resistance 210 has a negligible affect on the quality factor. Ideally, the parasitic resistances 204 and 208 are substantially reduced so as to be negligible.

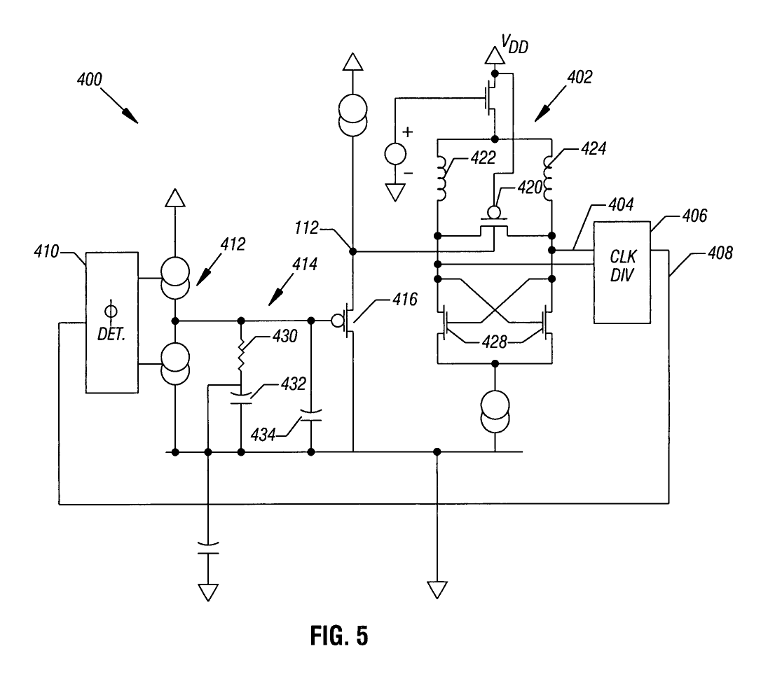

Referring to FIG. 5, a phase locked loop 400 is shown according to one embodiment. Other circuit implementations are also contemplated. The phase locked loop 400 includes a voltage controlled oscillator core 402, that outputs clock pulses 404 to an optional clock divider 406. In some embodiments having a clock divider, the clock divider 406 may divide the clock pulses 404 to lower frequency clock pulses 408, which are input to a phase detector 410. Alternatively, the division ratio may be one and the phase locked loop 400 has no clock divider. The phase detector 410 drives a charge pump 412, which drives a loop filter 414. The loop filter 414 drives the buffer 416, which drives the voltage controlled oscillator core 402 to output the clock pulses 404.

The VCO core 402 includes a CMOS varactor 420, which is represented by a P-MOSFET, whose gate is coupled to the voltage V_{DD} and whose substrate 110 is coupled to the controlled voltage supplied by the phase detector 410 through the buffer 416. The CMOS varactor 420 may be any CMOS varactor implemented according to an embodiment of the present invention.

The VCO core 402 may also include a pair of inductors 422, 424 formed in the same substrate with the CMOS varactor 420. The VCO core 402 also includes MOSFETs 426 and 428.

The loop filter 414 includes a resistor 430 and a pair of capacitors 432 and 434.

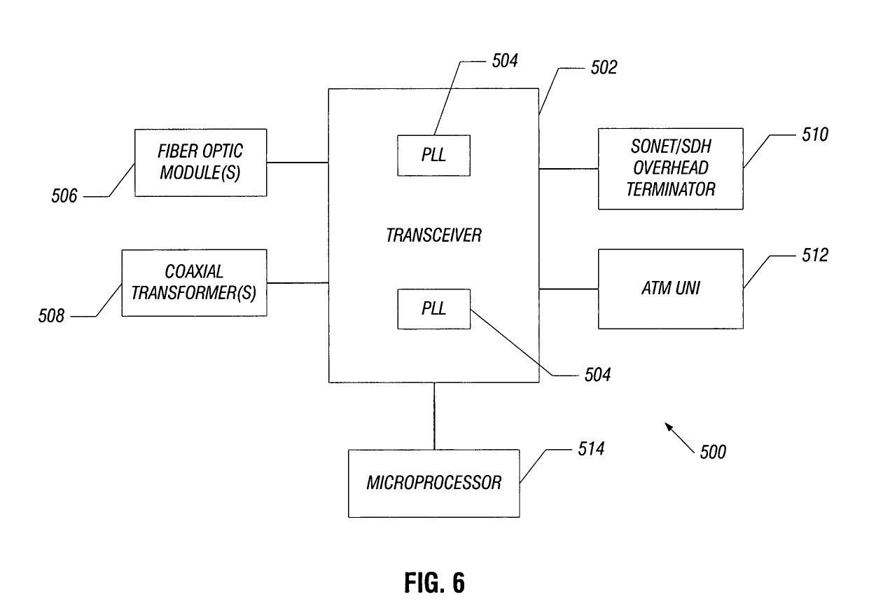

FIG. 6 is a high level diagram of a communication system 500 according to one embodiment. Other circuit implementations are also contemplated. The system 500 includes a transceiver 502 which may, for example, be a front end transceiver for a transmission application. The transceiver 502 includes a pair of phase locked loops 504 implemented according to an embodiment of the present invention.

The transceiver 502 may interface to one or more fiber optic modules 506 and/or coaxial transformers 508 on the line side and to a synchronous optical network (SONET)/synchronous digital hierarchy (SDH) overhead terminator 510 or an asynchronous transfer mode user network interface 512 on the system side, in one embodiment. The transceiver 502 may include a microprocessor 514, which may provide software mode control of the transceiver 502.

The system 500 may be suitable for use in an optical cross connect, optical add/drop multiplexers that operates at the optical carrier level, short haul serial links, access links for asynchronous transfer mode wide area networks, digital loop carriers, and other applications.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
performing a lightly doped drain implant while an MOS varactor is covered.

2. The method of claim 1 including performing a HALO implant while said varactor is covered.

3. The method of claim 1 including forming an accumulation MOS varactor.

4. The method of claim 1 including forming a varactor without a lightly doped drain region.

5. The method of claim 1 including reducing parasitic resistance of a MOS varactor by masking the lightly doped drain implant from the MOS varactor.

6. The method of claim 1 including forming a voltage controlled oscillator including said varactor.

7. The method of claim 6 including forming a phase locked loop including said voltage controlled oscillator.

8. An MOS varactor comprising:
a substrate;
a gate electrode over said substrate; and
source and drain regions formed in said substrate without lightly doped drain regions.

9. The varactor of claim 8 wherein said varactor is free of any HALO implant.

10. The varactor of claim 8 wherein said varactor is formed in a well in said substrate.

11. The varactor of claim 10, said well being more lightly doped than said source and drain regions, said well and said source and drain regions being of the same polarity.

12. The varactor of claim 8 wherein said varactor is an accumulation MOS varactor.

13. The varactor of claim 8 including a well, said gate electrode and said well being of the same polarity.

14. A voltage controlled oscillator comprising:
an MOS varactor having a gate electrode and source and drain regions free of any lightly doped drain region; and
an inductor coupled to said varactor.

15. The oscillator of claim 12 wherein said varactor is free of any HALO implant.

16. The oscillator of claim 14 including a well, said gate electrode and said well being of the same polarity.

17. The oscillator of claim 14 including a channel between said source and drain regions, said channel being more lightly doped than said source drain regions, said channel and said source and drain regions being of the same polarity.

18. A system comprising:
a voltage controlled oscillator including an MOS varactor, said MOS varactor including a substrate, source and drain regions formed in said substrate, and a gate electrode formed over said substrate, said varactor being without any lightly doped drain regions between the source/drain and the gate electrode;
a processor coupled to said oscillator; and
a fiber optic module coupled to said oscillator.

19. The system of claim 18 wherein said varactor is free of any HALO implant.

20. The system of claim 18, said varactor including a well, said gate electrode and said well being of the same polarity.
